(19) United States
(12) Patent Application Publication
(10) Pub. No.: US 2003/0175998 A1
(43) Pub. Date: Sep. 18, 2003

(54) Method for fabricating capacitor device

(75) Inventors: Yoshihisa Nagano, Osaka (JP); Shinichiro Hayashi, Osaka (JP); Yuji Judai, Kyoto (JP)

Correspondence Address: McDermott, Will & Emery, 600 13th Street, NW, Washington, DC, 20005-3096, US

(73) Assignee: Matsushita Electric Industrial Co., Ltd., Osaka (JP)

(21) Appl. No.: 10/322,526

(22) Filed: Dec. 19, 2002

(30) Foreign Application Priority Data
Mar. 15, 2002 (JP) 2002-071509

(51) Int. Cl. H01L 21/00; H01L 21/8242

(52) U.S. Cl. 438/3; 438/240; 438/393

(57) ABSTRACT

After forming a lower electrode by patterning a conducting film formed on a substrate by using an etching gas including chlorine, chlorine remaining on the lower electrode is removed by irradiating the lower electrode with plasma of a gas including fluorine. Thereafter, a capacitor dielectric film made of an insulating metal oxide is formed on the lower electrode, and an upper electrode is formed on the capacitor dielectric film.

### BACKGROUND OF THE INVENTION

The present invention relates to a method for fabricating a capacitor device including, as a capacitor dielectric film, a high dielectric film or a ferroelectric film made of an insulating metal oxide, and more particularly, it relates to a processing technique for a lower electrode of a capacitor device.

In accordance with recent development of digital technology, since more and more massive data are processed and stored, electronic equipment has been more and more highly developed, and semiconductor elements included in semiconductor devices used in the electronic equipment have been rapidly refined.

Accordingly, in order to realize a high degree of integration of a dynamic RAM, a technique to use, as a capacitor dielectric film, a high dielectric film instead of a conventional silicon oxide or silicon nitride is now being widely studied and developed.

Furthermore, in order to realize practical use of a nonvolatile RAM capable of not only operating at a low operation voltage but also performing high-speed read and write operations, a ferroelectric film having a spontaneous polarization characteristic is being earnestly studied.

In a semiconductor memory using, as a capacitor dielectric film, such a high dielectric film or ferroelectric film, when a memory with a high degree of integration of megabit class is desired to realize, a stack memory cell is used instead of a conventional planar memory cell.

One of the most significant techniques to realize a stack memory cell is a fine processing technique for a capacitor device. In particular, in a capacitor device included in a stack memory cell employed in a highly integrated memory of the megabit class, a capacitor dielectric film is formed to be in contact with the face of a previously processed lower electrode. Therefore, it is necessary to sufficiently grasp how the state of the face of the lower electrode resulting from the processing affects the characteristic of the capacitor dielectric film.

Now, a conventional method for fabricating a capacitor device disclosed in, for example, Japanese Laid-Open Patent Publication No. 11-354505 will be described with reference to FIGS. 9A through 9D.

First, as shown in FIG. 9A, a film having a conducting property and an oxygen barrier property, such as a first TaSiN film 102, is deposited over a protection insulating film 101 formed on a substrate 100. Then, a conducting film 103 of, for example, an Ir film is deposited on the first TaSiN film 102. Subsequently, a film with etching resistance, such as a second TaSiN film 104, is deposited on the conducting film 103, and then, a resist pattern 105 is formed on the second TaSiN film 104.

Next, as shown in FIG. 9B, the second TaSiN film 104 is dry etched by using an etching gas of a chlorine gas with the resist pattern 105 used as a mask, so as to form a hard mask 104A from the second TaSiN film 104. Thereafter, the resist pattern 105 is removed.

Then, as shown in FIG. 9C, the conducting film 103 is dry etched by using an etching gas of a mixed gas of chlorine and oxygen with the hard mask 104A used as a mask, so as to form a patterned conducting film 103A.

Subsequently, as shown in FIG. 9D, the hard mask 104A and the first TaSiN film 102 are dry etched by using an etching gas of a chlorine gas, so as to remove the hard mask 104A and form a conducting oxygen barrier film 102A from the first TaSiN film 102. In this manner, a lower electrode 106 composed of the patterned conducting film 103A and the conducting oxygen barrier film 102A is obtained.

When the present inventors fabricated a capacitor device by this conventional method, however, it was found that the characteristic of a capacitor dielectric film is degraded.

Therefore, the cause of the characteristic degradation of the capacitor dielectric film was variously examined, resulting in finding the following: At the stage of completing the procedure shown in FIG. 9D, namely, at the stage where the hard mask 104A has been removed and the oxygen barrier film 102A has been formed from the first TaSiN film 102, chlorine included in the etching gas remains on the top and side faces of the lower electrode 106 as shown in FIG. 10, and the remaining chlorine atoms degrade the characteristic of the capacitor dielectric film.

FIG. 11 shows remnant polarization obtained by applying a voltage of 1.8 V to a conventional capacitor device and a comparative capacitor device. The conventional capacitor device is fabricated as follows: A multilayer film of Pt/IrO₂Ir/TiAlN stacked in this order in the downward direction is patterned by the aforementioned conventional method to form a lower electrode, and a capacitor dielectric film of a ferroelectric film such as SrBi₂(Ta,Nb)₂O₉ is formed on the lower electrode. On the other hand, the comparative capacitor device is fabricated as follows: The same multilayer film is used without patterning and a capacitor dielectric film of the same ferroelectric film is formed on the multilayer film. As is understood from FIG. 11, the remnant polarization of the conventional capacitor device is much poorer than that of the comparative capacitor device.

FIG. 12 shows mechanism of degradation of the capacitor dielectric film of the conventional capacitor device, and specifically, mechanism of generation of impurities on the interface between the lower electrode 106 and a capacitor dielectric film 108 formed thereon. In FIG. 12, a reference numeral 107 denotes an insulating film formed around the lower electrode 106.

On the interface between the lower electrode 106 and the capacitor dielectric film 108, a chemical reaction is caused between the chlorine, which remains on the lower electrode 106 and has high reactivity, and elements constituting the capacitor dielectric film 108. As a result, impurities including chloride are generated. For example, in the case where the capacitor dielectric film 108 is made of SrBi₂(Ta,Nb)₂O₉, impurities including chlorides (such as SrClₓ and TaClₓ) are comparatively easily generated.

### SUMMARY OF THE INVENTION

In consideration of the above-described conventional problem, an object of the invention is preventing the characteristic degradation of a capacitor dielectric film by preventing generation of impurities on the interface between a lower electrode and the capacitor dielectric film.

In order to achieve the object, the first method for fabricating a capacitor device of this invention includes the steps of forming a lower electrode by patterning a conducting film formed on a substrate by using an etching gas including chlorine; removing chlorine remaining on the lower electrode by irradiating the lower electrode with plasma of a gas including fluorine; forming a capacitor dielectric film made of an insulating metal oxide on the lower electrode; and forming an upper electrode on the capacitor dielectric film.

In the first method for fabricating a capacitor device, since the lower electrode is irradiated with the plasma of the gas including fluorine, chemically stable fluorine can be easily substituted for the chlorine remaining on the lower electrode. Therefore, impurities can be prevented from being generated through a chemical reaction between the chlorine remaining on the lower electrode and the capacitor dielectric film, resulting in preventing characteristic degradation of the capacitor dielectric film.

In the first method for fabricating a capacitor device, the gas including fluorine is preferably a gas including CF₄.

Thus, active hydrogen atoms are not generated as compared with the case where a gas including hydrogen such as CHF₃ is used, and hence, a conducting oxide such as IrO₂ or RuO₂ included in the conducting film can be prevented from being reduced by the active hydrogen atoms. Accordingly, the chemically stable fluorine can be definitely substituted for the remaining chlorine.

The second method for fabricating a capacitor device of this invention includes the steps of forming a lower electrode by patterning a conducting film formed on a substrate by using an etching gas including chlorine; removing chlorine remaining on the lower electrode by annealing the substrate; forming a capacitor dielectric film made of an insulating metal oxide on the lower electrode; and forming an upper electrode on the capacitor dielectric film.

In the second method for fabricating a capacitor device, since the substrate is annealed, the chlorine remaining on the lower electrode can be easily released by using thermal energy. Accordingly, impurities can be prevented from being generated through the chemical reaction between the chlorine remaining on the lower electrode and the capacitor dielectric film, resulting in preventing the characteristic degradation of the capacitor dielectric film.

In the second method for fabricating a capacitor device, the substrate is annealed preferably at a temperature not less than 150° C. and not more than 650° C.

Thus, the chlorine can be sufficiently released without thermally decomposing IrO₂, RuO₂ or the like included in the conducting film.

In the second method for fabricating a capacitor device, the step of removing chlorine remaining on the lower electrode preferably includes a sub-step of annealing the substrate while irradiating the lower electrode with plasma of a gas including oxygen.

Thus, the lower electrode is irradiated with active oxygen plasma, and hence, the release of the chlorine can be accelerated.

The third method for fabricating a capacitor device of this invention includes the steps of forming a lower electrode by patterning a conducting film formed on a substrate by using an etching gas including chlorine; removing chlorine remaining on the lower electrode by cleaning the lower electrode with water; forming a capacitor dielectric film made of an insulating metal oxide on the lower electrode; and forming an upper electrode on the capacitor dielectric film.

In the third method for fabricating a capacitor device, the lower electrode is cleaned with water, and hence, the chlorine remaining on the lower electrode can be dissolved in the water to be washed away. Accordingly, impurities can be prevented from being generated through the chemical reaction between the chlorine remaining on the lower electrode and the capacitor dielectric film, resulting in preventing the characteristic degradation of the capacitor dielectric film.

In any of the first through third methods for fabricating a capacitor device, the step of forming a lower electrode preferably includes the sub-steps of forming an etching resistance film on the conducting film; patterning the etching resistance film into a hard mask; and patterning the conducting film and removing the hard mask by etching the conducting film and the hard mask by using the etching gas.

Thus, the hard mask made from the etching resistance film is used as an etching mask, and hence, the thickness of the mask can be reduced to 600 nm or less. Therefore, a fence can be prevented from being formed at the edge of the patterned conducting film, namely, the lower electrode. Also, since the lower electrode can be patterned to have a substantially vertical cross-sectional shape, the lower electrode can be reduced to a width of approximately 0.5 μm.

In this case, the etching resistance film is preferably made of Ti, TiN, TIAlN, TiSiN, Ta, TaN, TaAlN or TaSiN.

Thus, in patterning the conducting film by using the etching gas including chlorine, the etching rate of the etching resistance film is approximately 1/100 of that of the conducting film. Therefore, a hard mask with etching resistance can be definitely formed.

In any of the first through third methods for fabricating a capacitor device, the step of forming a lower electrode preferably includes the sub-steps of forming a resist pattern on the conducting film; and etching the conducting film by using the etching gas with the resist pattern used as a mask.

Thus, the conducting film can be patterned by a simple method.

In any of the first through third methods for fabricating a capacitor device, the conducting film is preferably a multilayer film including an upper film of Pt, IrO₂, Ir, RuO₂ or Ru.

Thus, the resultant capacitor device can attain a good electric characteristic with a minimum leakage current.

In any of the first through third methods for fabricating a capacitor device, the conducting film is preferably a multilayer film including a lower film having a conducting property and an oxygen barrier property.

Thus, in annealing performed in an oxygen atmosphere, which is indispensable in crystallizing the insulating metal oxide included in the capacitor dielectric film, oxygen can be prevented from diffusing into the lower electrode to reach a layer below the lower electrode. Therefore, for example, in a stack memory cell, the face of a conducting plug connected to the lower face of the lower electrode can be prevented from being oxidized to cause a contact failure. Also, polysilicon, tungsten or the like included in the conducting plug can be prevented from diffusing into the lower electrode to reach the capacitor dielectric film, resulting in preventing the characteristic degradation of the capacitor dielectric film.

In this case, the lower film is preferably made of TiAlN, TiSiN, TaAlN or TaSiN.

Thus, the diffusion of oxygen or the conducting plug material can be definitely prevented.

In any of the first through third methods for fabricating a capacitor device, the insulating metal oxide is preferably SrBi₂(TaₓNb₁₋ₓ)₂O₉, wherein 0≦x≦1, (BiₓLa₁₋ₓ) ₄Ti₃O₁₂, wherein 0≦x≦1, (PbₓZr₁₋ₓ)TiO₃, wherein 0≦x≦1 or (BaₓSr₁₋ₓ)TiO₃, wherein 0≦x≦1.

Thus, the resultant capacitor device can attain a good electric characteristic.

### BRIEF DESCRIPTION OF THE DRAWINGS

FIGS. 1A, 1B, 1C, 1D and 1E are cross-sectional views for showing procedures in a method for fabricating a capacitor device according to Embodiment 1 of the invention;

FIGS. 2A and 2B are cross-sectional views for showing other procedures in the method for fabricating a capacitor device of Embodiment 1;

FIG. 3 is a diagram for showing the result of an experiment carried out for evaluating the characteristic of a capacitor device obtained by the method for fabricating a capacitor device of Embodiment 1;

FIGS. 4A, 4B, 4C and 4D are cross-sectional views for showing procedures in a method for fabricating a capacitor device according to a modification of Embodiment 1;

FIG. 5 is a cross-sectional view of another exemplified capacitor device obtained by the method for fabricating a capacitor device of Embodiment 1;

FIG. 6 is a cross-sectional view for showing an example of a method for fabricating a capacitor device according to Embodiment 2 of the invention;

FIG. 7 is a cross-sectional view for showing another example of the method for fabricating a capacitor device of Embodiment 2;

FIG. 8 is a cross-sectional view for showing a method for fabricating a capacitor device according to Embodiment 3 of the invention;

FIGS. 9A, 9B, 9C and 9D are cross-sectional views for showing procedures in a conventional method for fabricating a capacitor device;

FIG. 10 is a cross-sectional view for explaining a problem of a lower electrode obtained by the conventional method for fabricating a capacitor device;

FIG. 11 is a diagram for showing the result of an experiment carried out for evaluating the characteristic of a conventional capacitor device; and

FIG. 12 is a cross-sectional view for explaining mechanism of generation of impurities in the conventional method for fabricating a capacitor device.

### DETAILED DESCRIPTION OF THE INVENTION

Embodiment 1

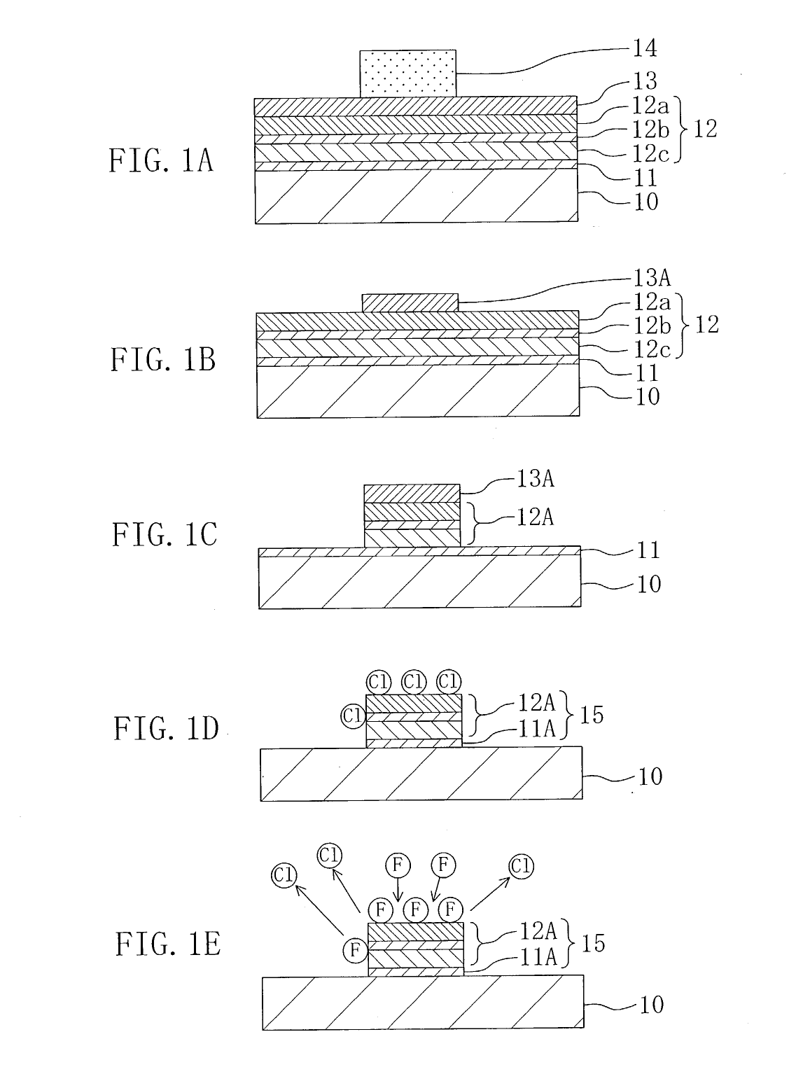

A method for fabricating a capacitor device according to Embodiment 1 of the invention will now be described with reference to FIGS. 1A through 1E, 2A, 2B and 3.

First, as shown in FIG. 1A, a film having a conducting property and an oxygen barrier property, such as a first TiAlN film 11 with a thickness of 20 through 100 nm, is deposited over a substrate 10 by sputtering. Then, a conducting film 12 made from a multilayer film of Pt/IrO₂/Ir stacked in this order in the downward direction is deposited on the first TiAlN film 11 by the sputtering. As the conducting film 12, a multilayer film including a Pt film 12a with a thickness of 50 through 100 nm, an IrO₂ film 12b with a thickness of 50 through 100 nm and an Ir film 12c with a thickness of 50 through 100 nm can be used.

Next, a film with etching resistance, such as a second TiAlN film 13 with a thickness of 20 through 150 nm, is deposited over the conducting film 12, and a resist pattern 14 is formed on the second TiAlN film 13.

Then, as shown in FIG. 1B, the second TiAlN film 13 is dry etched by using an etching gas including chlorine with the resist pattern 14 used as a mask, thereby forming a hard mask 13A from the second TiAlN film 13. Thereafter, the resist pattern 14 is removed.

Next, as shown in FIG. 1C, the conducting film 12 is dry etched by using an etching gas of a mixed gas of chlorine and oxygen with the hard mask 13A used as a mask, thereby forming a patterned conducting film 12A. In this etching, the hard mask 13A is minimally etched. For example, in the case where the flow ratio between chlorine and oxygen is 2:1, the etching rate of the hard mask 13A is approximately 1/100 of that of the conducting film 12.

Thereafter, as shown in FIG. 1D, the hard mask 13A and the first TiAlN film 11 are dry etched by using an etching gas including chlorine, thereby removing the hard mask 13A and forming a conducting barrier film 11A from the first TiAlN film 11. When a lower electrode 15 composed of the patterned conducting film 12A and the conducting barrier film 11A is thus formed, chlorine included in the etching gas remains in a large amount on the lower electrode 15.

Subsequently, as shown in FIG. 1E, the lower electrode 15 is irradiated with plasma of a gas including fluorine, so that the remaining chlorine can be removed by substituting fluorine for the chlorine remaining on the lower electrode 15. For example, when the lower electrode is irradiated with plasma generated by discharging a CF₄ gas, that is, the gas including fluorine, for 30 seconds or more, the remaining chlorine can be removed.

In Embodiment 1, by irradiating the lower electrode 15 with the plasma of the gas including fluorine, chemically stable fluorine can be easily substituted for the remaining chlorine. Therefore, impurities can be prevented from being generated through a chemical reaction between the remaining chlorine and a capacitor dielectric film to be formed on the lower electrode 15, resulting in improving the characteristic of the capacitor dielectric film.

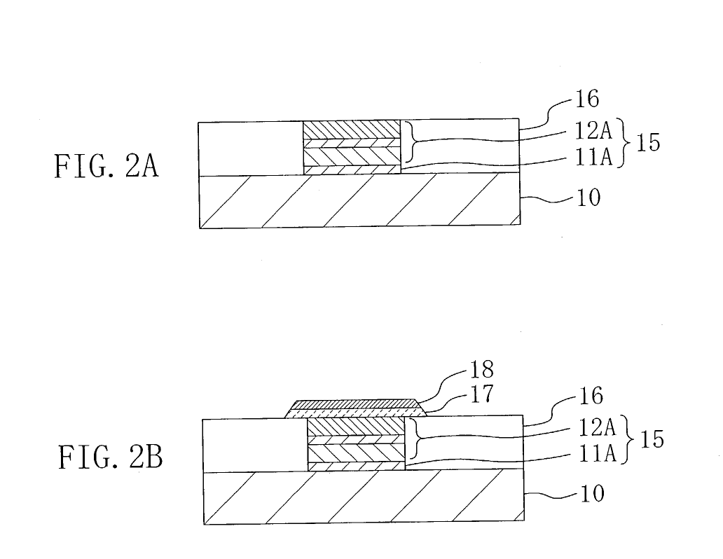

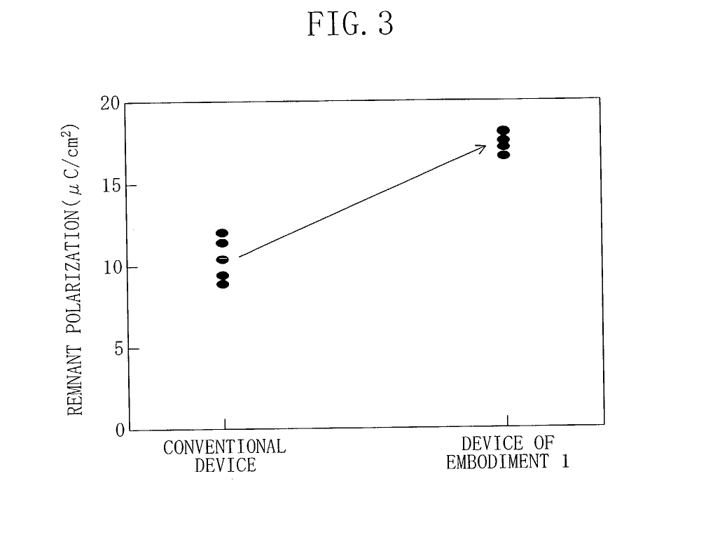

Now, the result of an experiment carried out for evaluating the characteristic of a capacitor device obtained in Embodiment 1 will be described with reference to FIGS. 2A, 2B and 3.

First, a silicon oxide film is deposited over the lower electrode 15 and the substrate 10 after irradiating the lower electrode 15 with the plasma of the gas including fluorine, and the silicon oxide film is planarized by CMP (chemical mechanical polishing). Thus, an insulating film 16 is formed around the lower electrode 15 as shown in FIG. 2A.

Next, a ferroelectric film of SrBi₂(TaₓNb₁₋ₓ)₂O₉ (wherein 0≦x≦1) with a thickness of 50 through 150 nm is deposited on the lower electrode 15 and the insulating film 16 by MOD (metal organic deposition), MOCVD (metal organic CVD) or the sputtering. Thereafter, a Pt film with a thickness of 50 through 100 nm is deposited on the ferroelectric film by the sputtering, and the Pt film and the ferroelectric film are patterned. Thus, a capacitor dielectric film 17 and an upper electrode 18 are formed respectively from the ferroelectric film and the Pt film as shown in FIG. 2B. In this manner, a capacitor device including the lower electrode 15, the capacitor dielectric film 17 and the upper electrode 18 can be obtained.

FIG. 3 shows remnant polarization obtained by applying a voltage of 1.8 V to the capacitor device fabricated in Embodiment 1 and a capacitor device fabricated by the conventional method. As is understood from FIG. 3, the remnant polarization of the capacitor device obtained by the method of Embodiment 1 is largely improved as compared with that of the capacitor device obtained by the conventional method.

Modification of Embodiment 1

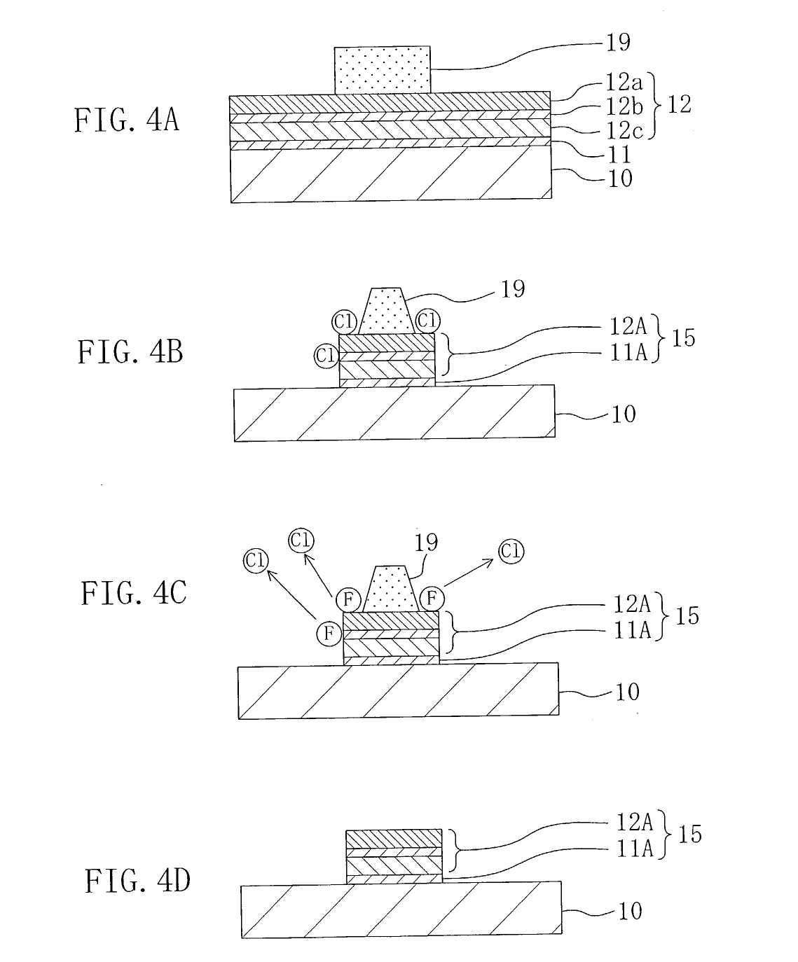

A method for fabricating a capacitor device according to a modification of Embodiment 1 will now be described with reference to FIGS. 4A through 4D.

First, as shown in FIG. 4A, a film having a conducting property and an oxygen barrier property, such as a TiAlN film 11 with a thickness of 20 through 100 nm, is deposited over a substrate 10 by the sputtering. Then, a conducting film 12 of a multilayer film of Pt/IrO₂/Ir stacked in this order in the downward direction is deposited on the TiAlN film 11 by the sputtering. As the conducting film 12, a multilayer film including a Pt film 12a with a thickness of 50 through 100 nm, an IrO₂ film 12b with a thickness of 50 through 100 nm and an Ir film 12c with a thickness of 50 through 100 nm can be used. Then, a resist pattern 19 is formed on the conducting film 12.

Next, as shown in FIG. 4B, the conducting film 12 and the TiAlN film 11 are dry etched by using an etching gas of a mixed gas of chlorine and argon with the resist pattern 19 used as a mask, thereby forming a patterned conducting film 12A and a conducting barrier film 11A from the TiAlN film 11. When a lower electrode 15 composed of the patterned conducting film 12A and the conducting barrier layer 11A is thus formed, chlorine included in the etching gas remains in a large amount on a portion of the lower electrode 15 not covered with the resist pattern 19.

Then, as shown in FIG. 4C, the lower electrode 15 is irradiated with plasma of a gas including fluorine, so that the remaining chlorine can be removed by substituting fluorine for the chlorine remaining on the lower electrode 15. For example, when the lower electrode is irradiated with plasma generated by discharging a CF₄ gas, that is, the gas including fluorine, for 30 seconds or more, the remaining chlorine can be removed.

Thereafter, the resist pattern 19 is removed as shown in FIG. 4D.

In the modification of Embodiment 1, the lower electrode 15 is irradiated with the plasma of the gas including fluorine in the same manner as in Embodiment 1, and therefore, impurities can be prevented from being generated through the chemical reaction between the remaining chlorine and a capacitor dielectric film to be formed on the lower electrode 15. As a result, the characteristic of the capacitor dielectric film can be improved.

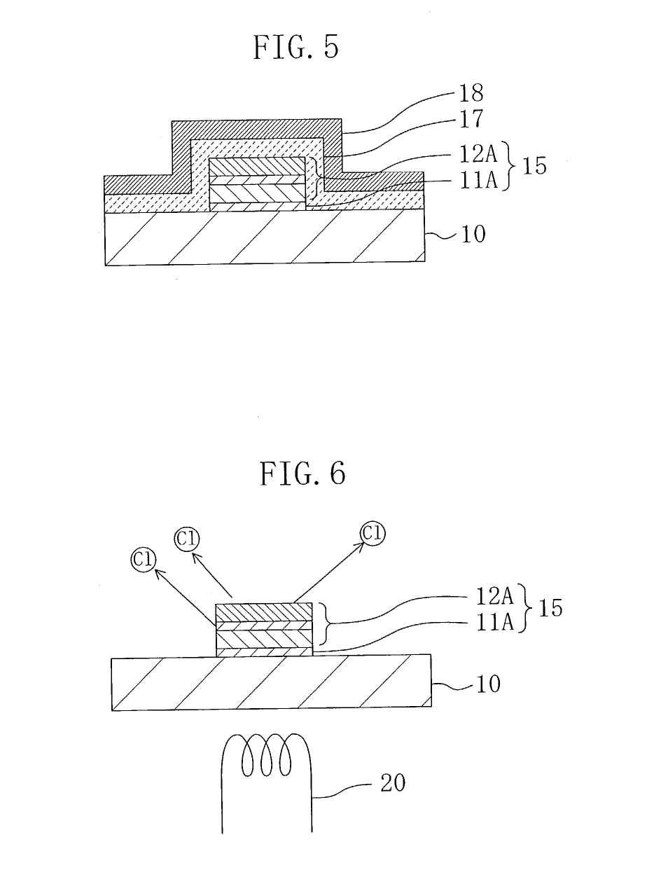

In Embodiment 1 and the modification, a capacitor device having a structure as shown in FIG. 2B is fabricated, but a capacitor device having a structure as shown in FIG. 5 may be also fabricated. Specifically, in the capacitor device shown in FIG. 5, no insulating film 16 is formed around a lower electrode 15, a capacitor dielectric film 17 covering the top and side faces of the lower electrode 15 is formed on a substrate 10, and an upper electrode 18 is formed on the capacitor dielectric film 17.

In the capacitor device having such a structure, the contact area between the lower electrode 15 and the capacitor dielectric film 17 is so large that the effect of the invention can be remarkably exhibited.

Embodiment 2

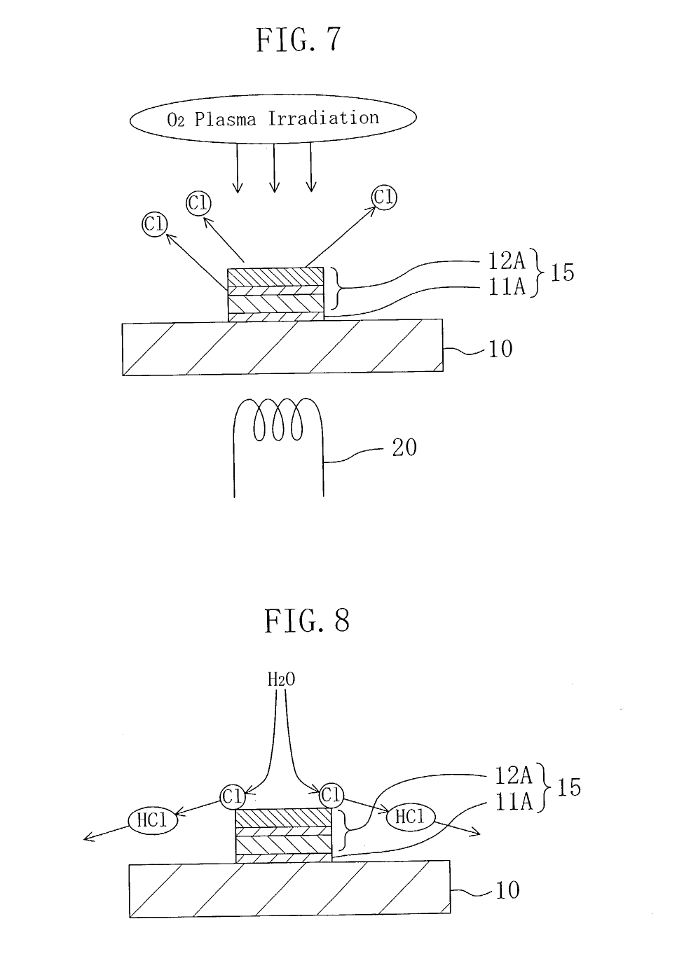

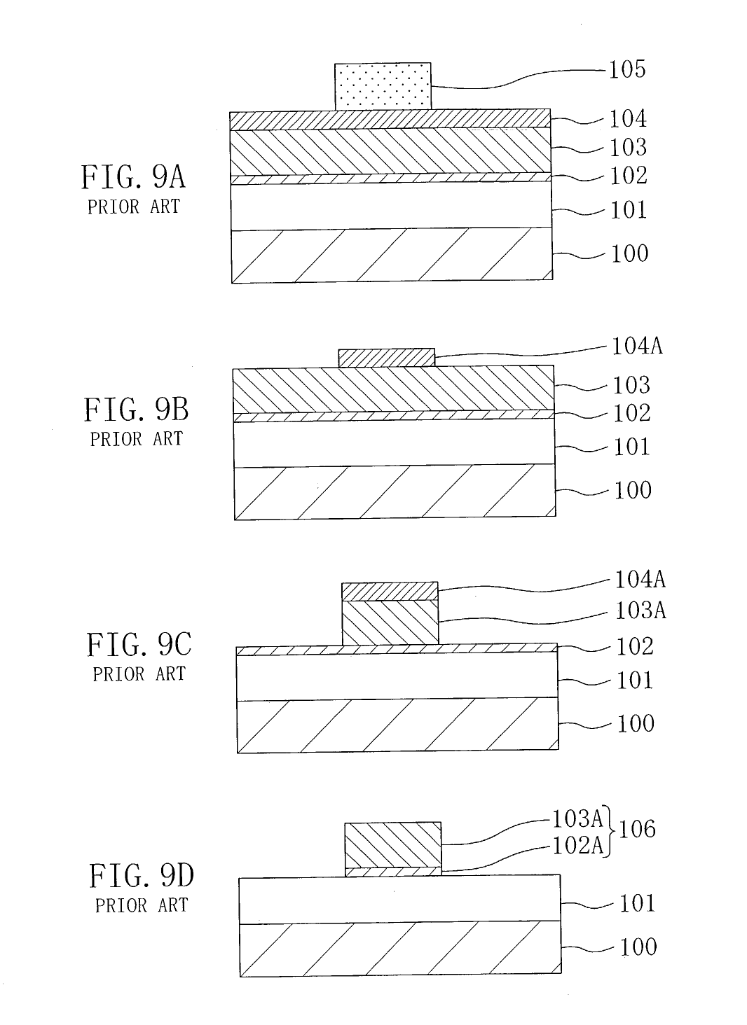

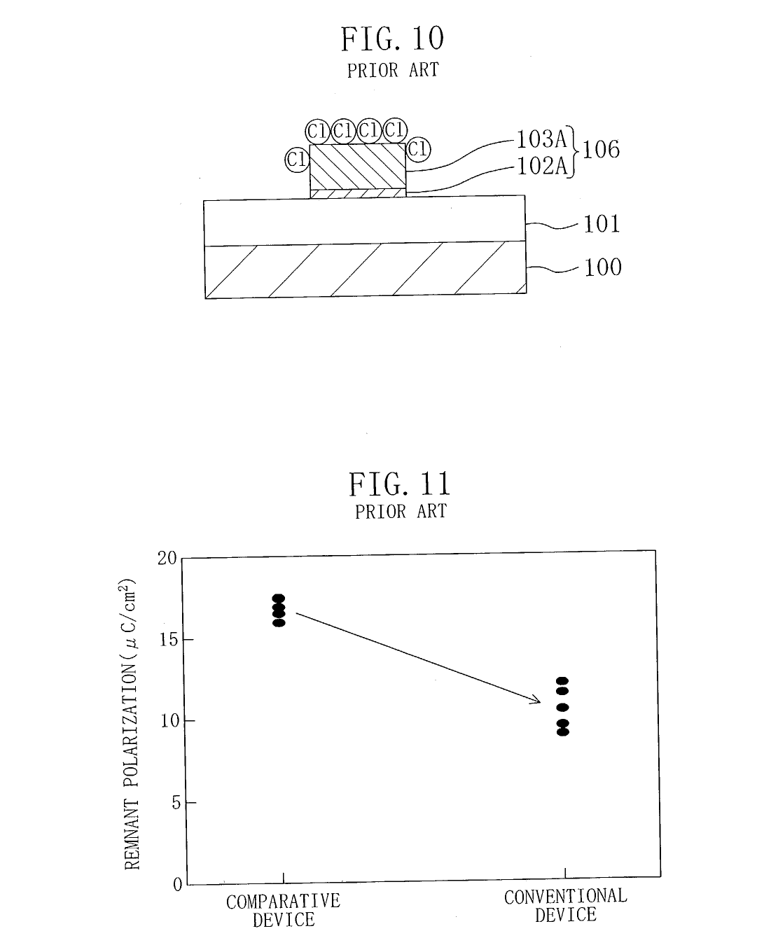

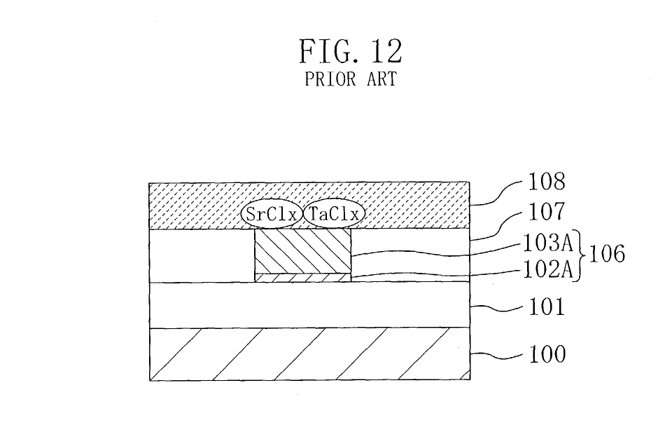

A method for fabricating a capacitor device according to Embodiment 2 of the invention will now be described with reference to FIGS. 6 and 7.

As shown in FIG. 6, in the same manner as in Embodiment 1, a lower electrode 15 composed of a patterned conducting film 12A and a conducting barrier film 11A is formed on a substrate 10, and thereafter, the substrate 10 is annealed with a heater 20, thereby releasing chlorine remaining on the lower electrode 15. The annealing temperature for the substrate 10 is preferably not less than 150° C. and not more than 650° C. In an experiment carried out by the present inventors, the chlorine cannot be sufficiently released when the annealing temperature is lower than 150° C. Also, when the annealing temperature exceeds 650° C., IrO₂, RuO₂ or the like included in the lower electrode 15 is thermally decomposed, and hence, the characteristic of the resultant capacitor device is harmfully affected.

Alternatively, the substrate 10 may be annealed with the heater 20 while irradiating the lower electrode 15 with plasma of a gas including oxygen as shown in FIG. 7. In this manner, the face of the lower electrode 15 is irradiated with active oxygen plasma, which accelerates the release of the chlorine remaining on the lower electrode 15.

In this case, the irradiation of the lower electrode 15 with the plasma of the gas including oxygen can be employed in the method for fabricating a capacitor device according to the modification of Embodiment 1, so that the procedure for removing the resist pattern 19 and the procedure for irradiating the lower electrode 15 with the plasma of the gas including oxygen can be simultaneously performed. Thus, the number of fabrication procedures can be reduced.

Since the chlorine remaining on the lower electrode 15 is released by annealing the substrate 10 in Embodiment 2, impurities can be prevented from being generated through the chemical reaction between the remaining chlorine and a capacitor dielectric film to be formed on the lower electrode 15, resulting in improving the characteristic of the capacitor dielectric film.

Also, when the annealing of the substrate 10 and the oxygen plasma irradiation of the lower electrode are simultaneously performed, the release of the chlorine remaining on the lower electrode 15 can be accelerated.

Embodiment 3

A method for fabricating a capacitor device according to Embodiment 3 of the invention will now be described with reference to FIG. 8.

As shown in FIG. 8, in the same manner as in Embodiment 1, a lower electrode 15 composed of a patterned conducting film 12A and a conducting barrier film 11A is formed on a substrate 10, and thereafter, chlorine remaining on the lower electrode 15 is removed by cleaning the lower electrode 15 with water. In this manner, a chemical reaction is caused between hydrogen generated through decomposition of water and the remaining chlorine, so as to generate hydrochloric acid (HCl), which is removed together with water. Accordingly, the chlorine remaining on the lower electrode 15 can be easily removed. In this case, the temperature of the water used for cleaning the lower electrode 15 is preferably high, and when water with a temperature of 60° C. or more, namely, warm water is used, the effect to remove the chlorine can be improved.

In Embodiment 3, the chlorine remaining on the lower electrode 15 can be dissolved in water to be washed away by cleaning the lower electrode 15 with water. Therefore, impurities can be prevented from being generated through the chemical reaction between the remaining chlorine and a capacitor dielectric film to be formed on the lower electrode 15, resulting in improving the characteristic of the capacitor dielectric film.

Although the first TiAlN film 11 is used as the film having a conducting property and an oxygen barrier property in Embodiment 1, 2 or 3, a TiSiN film, a TaAlN film or a TaSiN film may be used instead.

Although the multilayer film including Pt/IrO₂/Ir stacked in this order in the downward direction is used as the conducting film 12 in Embodiment 1, 2 or 3, a single-layer film made from a Pt film, an IrO₂ film, an Ir film, a RuO₂ film or a Ru film, or a multilayer film including any of these films appropriately stacked may be used instead.

Although the second TiAlN film 13 is used as the film with etching resistance in Embodiment 1, 2 or 3, a Ti film, a TiN film, a TiSiN film, a Ta film, a TaN film, a TaAlN film or a TaSiN film may be used instead.

Although the ferroelectric film of SrBi₂(TaₓNb₁₋ₓ)₂O₉ (wherein 0≦x≦1) is used as the capacitor dielectric film 17 in Embodiment 1, 2 or 3, an insulating metal oxide of (BiₓLa₁₋ₓ)₄Ti₃O₁₂ (wherein 0≦x≦1), (PbₓZr₁₋ₓ)TiO₃ (wherein 0≦x≦1) or (BaₓSr₁₋ₓ)TiO₃ (wherein 0≦x≦1) may be used instead.

What is claimed is:

1. A method for fabricating a capacitor device comprising the steps of:
forming a lower electrode by patterning a conducting film formed on a substrate by using an etching gas including chlorine;
removing chlorine remaining on said lower electrode by irradiating said lower electrode with plasma of a gas including fluorine;
forming a capacitor dielectric film made of an insulating metal oxide on said lower electrode; and
forming an upper electrode on said capacitor dielectric film.

2. The method for fabricating a capacitor device of claim 1,
wherein said gas including fluorine is a gas including CF₄.

3. The method for fabricating a capacitor device of claim 1,
wherein the step of forming a lower electrode includes the sub-steps of:
forming an etching resistance film on said conducting film;
patterning said etching resistance film into a hard mask; and
patterning said conducting film and removing said hard mask by etching said hard mask and said conducting film by using said etching gas.

4. The method for fabricating a capacitor device of claim 3,
wherein said etching resistance film is made of Ti, TiN, TiAlN, TiSiN, Ta, TaN, TaAlN or TaSiN.

5. The method for fabricating a capacitor device of claim 1,
wherein the step of forming a lower electrode includes the sub-steps of:
forming a resist pattern on said conducting film; and
etching said conducting film by using said etching gas with said resist pattern used as a mask.

6. The method for fabricating a capacitor device of claim 1,
wherein said conducting film is a multilayer film including an upper film of Pt, IrO₂, Ir, RuO₂ or Ru.

7. The method for fabricating a capacitor device of claim 1,
wherein said conducting film is a multilayer film including a lower film having a conducting property and an oxygen barrier property.

8. The method for fabricating a capacitor device of claim 7,
wherein said lower film is made of TiAlN, TiSiN, TaAlN or TaSiN.

9. The method for fabricating a capacitor device of claim 1,
wherein said insulating metal oxide is SrBi₂(TaₓNb₁₋ₓ)₂O₉, wherein 0≦x≦1, (BiₓLa₁₋ₓ)₄Ti₃O₁₂, wherein 0≦x≦1, (PbₓZr₁₋ₓ)TiO₃, wherein 0≦x≦1 or (BaₓSr₁₋ₓ)TiO₃, wherein 0≦x≦1.

10. A method for fabricating a capacitor device comprising the steps of:
forming a lower electrode by patterning a conducting film formed on a substrate by using an etching gas including chlorine;
removing chlorine remaining on said lower electrode by annealing said substrate;
forming a capacitor dielectric film made of an insulating metal oxide on said lower electrode; and
forming an upper electrode on said capacitor dielectric film.

11. The method for fabricating a capacitor device of claim 10,
wherein said substrate is annealed at a temperature not less than 150° C. and not more than 650° C.

12. The method for fabricating a capacitor device of claim 10,
wherein the step of removing chlorine remaining on said lower electrode includes a sub-step of annealing said substrate while irradiating said lower electrode with plasma of a gas including oxygen.

13. The method for fabricating a capacitor device of claim 10,
wherein the step of forming a lower electrode includes the sub-steps of:
forming an etching resistance film on said conducting film;
patterning said etching resistance film into a hard mask; and
patterning said conducting film and removing said hard mask by etching said hard mask and said conducting film by using said etching gas.

14. The method for fabricating a capacitor device of claim 13,
wherein said etching resistance film is made of Ti, TiN, TiAlN, TiSiN, Ta, TaN, TaAlN or TaSiN.

15. The method for fabricating a capacitor device of claim 10,
wherein the step of forming a lower electrode includes the sub-steps of:
forming a resist pattern on said conducting film; and
etching said conducting film by using said etching gas with said resist pattern used as a mask.

16. The method for fabricating a capacitor device of claim 10,
wherein said conducting film is a multilayer film including an upper film of Pt, IrO₂, Ir, RuO₂ or Ru.

17. The method for fabricating a capacitor device of claim 10,
wherein said conducting film is a multilayer film including a lower film having a conducting property and an oxygen barrier property.

18. The method for fabricating a capacitor device of claim 17,
wherein said lower film is made of TiAlN, TiSiN, TaAlN or TaSiN.

19. The method for fabricating a capacitor device of claim 10,
wherein said insulating metal oxide is SrBi₂(TaₓNb₁₋ₓ)₂O₉, wherein 0≦x≦1, (BiₓLa₁₋ₓ)₄Ti₃O₁₂, wherein 0≦x≦1, (PbₓZr₁₋ₓ)TiO₃, wherein 0≦x≦1 or (BaₓSr₁₋ₓ)TiO₃, wherein 0≦x≦1.

20. A method for fabricating a capacitor device comprising the steps of:
forming a lower electrode by patterning a conducting film formed on a substrate by using an etching gas including chlorine;
removing chlorine remaining on said lower electrode by cleaning said lower electrode with water;
forming a capacitor dielectric film made of an insulating metal oxide on said lower electrode; and
forming an upper electrode on said capacitor dielectric film.

21. The method for fabricating a capacitor device of claim 20,
wherein the step of forming a lower electrode includes the sub-steps of:
forming an etching resistance film on said conducting film;
patterning said etching resistance film into a hard mask; and
patterning said conducting film and removing said hard mask by etching said hard mask and said conducting film by using said etching gas.

22. The method for fabricating a capacitor device of claim 21,
wherein said etching resistance film is made of Ti, TiN, TiAlN, TiSiN, Ta, TaN, TaAlN or TaSiN.

23. The method for fabricating a capacitor device of claim 20,
wherein the step of forming a lower electrode includes the sub-steps of:
forming a resist pattern on said conducting film; and
etching said conducting film by using said etching gas with said resist pattern used as a mask.

24. The method for fabricating a capacitor device of claim 20,
wherein said conducting film is a multilayer film including an upper film of Pt, IrO₂, Ir, RuO₂ or Ru.

25. The method for fabricating a capacitor device of claim 20,
wherein said conducting film is a multilayer film including a lower film having a conducting property and an oxygen barrier property.

26. The method for fabricating a capacitor device of claim 25,
wherein said lower film is made of TiAlN, TiSiN, TaAlN or TaSiN.

27. The method for fabricating a capacitor device of claim 20,
wherein said insulating metal oxide is SrBi₂(TaₓNb₁₋ₓ)₂O₉, wherein 0≦x≦1, (BiₓLa₁₋ₓ)₄Ti₃O₁₂, wherein 0≦x≦1, (PbₓZr₁₋ₓ)TiO₃, wherein 0≦x≦1 or (BaₓSr₁₋ₓ)TiO₃, wherein 0≦x≦1.
